(19) United States
(12) Patent Application Publication
(10) Pub. No.: US 2020/0092992 A1
(43) Pub. Date: Mar. 19, 2020

(54) FANOUT TRACE LAYOUT, DISPLAY PANEL, AND DISPLAY DEVICE

(71) Applicants: Chongqing HKC Optoelectronics Technology Co., Ltd., Chongqing (CN); HKC Corporation Limited, Shenzhen, (CN)

(72) Inventor: Zhongnian Liu, Chongqing (CN)

(73) Assignees: Chongqing HKC Optoelectronics Technology Co., Ltd., Chongqing (CN); HKC Corporation Limited, Shenzhen, Guangdong (CN)

(21) Appl. No.: 16/254,592

(22) Filed: Jan. 23, 2019

Related U.S. Application Data
(63) Continuation of application No. PCT/CN2018/114451, filed on Nov. 8, 2018.

(30) Foreign Application Priority Data
Sep. 13, 2018 (CN) 201811069476.5

(51) Int. Cl. H05K 1/02; H05K 1/03

(52) U.S. Cl. CPC H05K 1/0298; H05K 1/0353; G09G 3/3611; H05K 2201/09263; H05K 2201/09272; H05K 2201/09227

(57) ABSTRACT

Disclosed are a fanout trace layout, a display panel and a display device. The fanout trace layout comprises a plurality of first traces, an insulating layer and a plurality of second traces, the first trace and the second trace are alternately defined, and the adjacent first traces and the second traces are partially overlapped.

### CROSS REFERENCE TO RELATED APPLICATIONS

The present application is a Continuation Application of PCT Application No. PCT/CN2018/114451 filed on Nov. 8, 2018, which claims the benefit of Chinese Patent Application No. 201811069476.5, filed on Sep. 13, 2018, which is incorporated herein by reference in its entirety.

### TECHNICAL FIELD

The present application relates to the technical field of display, in particular, to a fanout trace layout, a display panel, and a display device.

### BACKGROUND

The LCD panel includes an active area with a plurality of pixels and an external lead bonding area at the periphery of the active area. The pixels inside the panel are electrically connected to the driver chip of the external lead bonding area through scanning lines and data lines. Due to the width difference between the transmission signal part of the driver chip and the corresponding data lines or scanning lines, the connected part of the transmission signal part of the driver chip and the corresponding data lines or scanning lines will form a fan-shaped trace, i.e. fanout trace layout. The central part of the fanout trace layout has a shorter trace and the side part has a longer trace, which makes a different impedance with different traces, resulting in the difference of input picture signals and affecting the display performance of the panel. At present, the objective of equalizing trace impedance can be achieved by improving the layout/shape of the traces, but when space is limited, the impedance difference between the central and side traces is still large.

### SUMMARY

The main purpose of the present application is to provide a fanout trace layout, aiming at solving the problem of the layout of fanout traces in a limited space.

In order to achieve the above objective, the present application discloses a fanout trace layout, which includes:

a first fanout layer and a second fanout layer; and

an insulating layer, defined between the first fanout layer and the second fanout layer; the first fanout layer, the insulating layer and the second fanout layer are defined from top to bottom.

The first fanout layer includes a plurality of first traces arranged at intervals. The second fanout layer includes a plurality of second traces arranged at intervals.

The first traces and the second traces are alternately defined, and the first traces and the second traces are partially overlapped when the first traces and the second traces are adjacently defined.

In some embodiments of the present application, the first traces include a winding portion and a straight portion. The first traces are defined in a direction from the center to two lateral sides. And an extending length of the winding portion of the first trace gradually decreases in the direction from the center to two lateral sides, while an extending length of the straight portion of the first trace gradually increases in the direction from the center to two lateral sides.

In some embodiments of the present application, the second traces include a winding portion and a straight portion. the second traces are defined in a direction from the center to two lateral sides, and an extending length of the winding portion of the second trace gradually decreases in the direction from the center to two lateral sides, while an extending length of the straight portion of the second trace gradually increases in the direction from the center to two lateral sides.

In some embodiments of the present application, the extending length of the winding portion of the first trace is larger than the extending length of the winding portion of the second trace that are adjacent to the first trace, and the extending length of the straight portion of the first trace is smaller than the extending length of the straight portion of the second trace that are adjacent to the first trace.

In some embodiments of the present application, the extending length of the winding portion of the first trace is smaller than the extending length of the winding portion of the second trace that are adjacent to the first trace. And the extending length of the straight portion of the first trace is larger than the extending length of the straight portion of the second trace that is adjacent to the first trace.

In some embodiments of the present application, the extending direction of the winding portion of the first trace is perpendicular to a length direction of the first fanout layer. And the extending direction of the straight portion of the first trace is inclined to the length direction of the first fanout layer.

The extending direction of the winding portion of the second trace is perpendicular to a length direction of the second fanout layer. And the extending direction of the straight portion of the second trace is inclined to the length direction of the second fanout layer.

In some embodiments of the present application, a width of the winding portion of the first trace is the same as a width of the winding portion of the second trace.

In some embodiments of the present application, a first lead is formed at the winding portion of the first trace, and a second lead is formed at the winding portion of the second trace. A distance between the first lead and the second lead of adjacent first traces and the second traces is P. A distance between two adjacent winding portions of the first traces is S, and a distance between two adjacent winding portions of the second traces is S, A width of the winding portion of the first trace is W, and a width of the winding portion of the second trace is W. And p<w≤2p−s.

In some embodiments of the present application, the insulating layer is a nitro-silicide layer.

The application also provides a display panel, which includes a fanout trace layout.

The fanout trace layout includes:

a first fanout layer and a second fanout layer; and

an insulating layer, defined between the first fanout layer and the second fanout layer; the first fanout layer, the insulating layer and the second fanout layer are defined from top to bottom.

The first fanout layer includes a plurality of first traces arranged at intervals. The second fanout layer includes a plurality of second traces arranged at intervals.

The first traces and the second traces are alternately defined, and the first traces and the second traces are partially overlapped when the first traces and the second traces are adjacently defined.

In some embodiments of the present application, the first traces include a winding portion and a straight portion. The first traces are defined in a direction from the center to two lateral sides. And an extending length of the winding portion of the first trace gradually decreases in the direction from the center to two lateral sides, while an extending length of the straight portion of the first trace gradually increases in the direction from the center to two lateral sides.

In some embodiments of the present application, the second traces include a winding portion and a straight portion. the second traces are defined in a direction from the center to two lateral sides, and an extending length of the winding portion of the second trace gradually decreases in the direction from the center to two lateral sides, while an extending length of the straight portion of the second trace gradually increases in the direction from the center to two lateral sides.

In some embodiments of the present application, the extending length of the winding portion of the first trace is larger than the extending length of the winding portion of the second trace that are adjacent to the first trace, and the extending length of the straight portion of the first trace is smaller than the extending length of the straight portion of the second trace that are adjacent to the first trace.

In some embodiments of the present application, the extending length of the winding portion of the first trace is smaller than the extending length of the winding portion of the second trace that are adjacent to the first trace. And the extending length of the straight portion of the first trace is larger than the extending length of the straight portion of the second trace that is adjacent to the first trace.

In some embodiments of the present application, the extending direction of the winding portion of the first trace is perpendicular to a length direction of the first fanout layer. And the extending direction of the straight portion of the first trace is inclined to the length direction of the first fanout layer.

The extending direction of the winding portion of the second trace is perpendicular to a length direction of the second fanout layer. And the extending direction of the straight portion of the second trace is inclined to the length direction of the second fanout layer.

In some embodiments of the present application, a width of the winding portion of the first trace is the same as a width of the winding portion of the second trace.

In some embodiments of the present application, a first lead is formed at the winding portion of the first trace, and a second lead is formed at the winding portion of the second trace. A distance between the first lead and the second lead of adjacent first traces and the second traces is P. A distance between two adjacent winding portions of the first traces is S, and a distance between two adjacent winding portions of the second traces is S, A width of the winding portion of the first trace is W, and a width of the winding portion of the second trace is W. And p<w≤2p−s.

In some embodiments of the present application, the insulating layer is a nitro-silicide layer.

In some embodiments of the present application, the display panel further comprises a substrate. The second traces, the insulating layer and the first traces are defined on the substrate.

The application also discloses a display device, which includes a display panel. The display panel include a fanout trace layout, and the fanout trace layout includes:

a first fanout layer and a second fanout layer; and

an insulating layer, defined between the first fanout layer and the second fanout layer; the first fanout layer, the insulating layer and the second fanout layer are defined from top to bottom.

The first fanout layer includes a plurality of first traces arranged at intervals. The second fanout layer includes a plurality of second traces arranged at intervals.

The first traces and the second traces are alternately defined, and the first traces and the second traces are partially overlapped when the first traces and the second traces are adjacently defined.

According to the technical solution of the application, the fanout trace layout includes the first traces and the second traces, and the first traces and the second traces are alternately defined. The adjacent first traces and the second traces partially overlap, and the first traces and the second traces are insulated from each other. In this way, through the structural layout of at least two layers, i.e., the first fanout layer and the second fanout layer, when the space is compressed, the design space of the first and second traces is greatly increased because the first fanout layer and the second fanout layer are overlap defined. The length of the different first traces and the second traces can be adjusted to be consistent from the center to the lateral sides, thereby minimizing the impedance difference between the first traces and the second traces or even making it disappears, so as to ensure stability of the signal transmission.

### BRIEF DESCRIPTION OF THE DRAWINGS

In order to explain the embodiments of the present application or the technical solutions in the prior art more clearly, the drawings that need to be used in the embodiments or the description of the prior art will be briefly described herein. Obviously, the drawings in the following description are only some embodiments of the present application. For those skilled in the art, other drawings can be conceived according to the structure shown in these drawings without paying creative effort.

FIG. 1 is a structural schematic diagram of the fanout traces according to some embodiments of the present application;

FIG. 2 is a schematic diagram of the first fanout layer in some embodiments of the present application;

FIG. 3 is a structural schematic diagram of the second fanout layer in some embodiments of the present application;

FIG. 4 is a cross-sectional view of a fanout trace layout in some embodiments of the present application.

### BRIEF DESCRIPTION OF THE REFERENCE NUMERALS

| Reference | |
|---|---|
| numeral | Name |
| 100 | The first |
| | fanout layer |
| 101 | Lead |
| 110 | First traces |
| 111 | winding portion |
| | of the first trace |
| 112 | straight portion |
| | of the first trace |
| 200 | The second |
| | fanout layer |
| 201 | Lead |
| 210 | Second traces |
| 211 | winding portion |
| | of the second |
| | trace |
| 212 | straight portion |
| | of the second |
| | trace |
| 300 | Insulating layer |

The implementation, functional features and advantages of the present application will be further described with reference to the accompanying drawings combining with the embodiments.

### DETAILED DESCRIPTION OF THE EMBODIMENTS

The technical solution in the embodiment of the present application will be described clearly and completely in the following with reference to the drawings in the embodiment of the present application. Obviously, the described embodiment is only a part of the exemplary embodiment of the present application, but not all of them. Based on the embodiments in the present application, all other embodiments conceived by those skilled in the art, shall fall into the protection scope of the present application.

It should be noted that all directional indications (such as up, down, left, right, front, back, etc.) in the embodiments of the present application are only used to explain the relative position and movement between the components in a certain posture (as shown in the drawings). If the specific position changes, the directional indications will also change accordingly.

In the present application, unless otherwise expressly specified and defined, the terms “connected”, “fixed” and the like shall be broadly understood. For example, “fixed” may be a fixed connection, a detachable connection, or an integral body. It can be a mechanical connection or an electrical connection. It can be directly connected or indirectly connected through an intermediate medium. It can be internal communication of two elements or the interaction relationship between two elements, unless otherwise clearly defined. For those skilled in the art, the specific meaning of the above terms in the present application can be understood according to the specific situation.

In addition, in the present application, the descriptions such as “first” and “second” are used for descriptive purposes only, and are not to be understood as indicating or implying its relative importance or implicitly indicating the number of indicated technical features. Thus, features defining “first” and “second” may explicitly or implicitly include at least one such feature. In addition, the technical solutions between the various embodiments may be combined with each other, but must be based on what one of ordinary skill in the art can achieve. When the combination of technical solutions is contradictory or impossible to achieve, it should be considered that the combination of such technical solutions does not exist and is not included within the protection scope required by the present application.

The display panel includes an active area including a plurality of pixels and an external lead bonding area at the periphery of the active area, the plurality of pixels defined in the active area are used for picture display. The external lead bonding area is defined with a driving chip, and the driving chip needs to be connected to the active area through traces to drive displaying of the active area. Due to the width difference between the transmission signal part of the driver chip and the corresponding data lines or scanning lines, the connected part of the transmission signal part of the driver chip and the corresponding data lines or scanning lines will form a fan-shaped traces layout.

Specifically, the active area comprises a plurality of scanning lines and a plurality of data lines, and the plurality of scanning lines and the plurality of data lines are intersected in the active area to form a plurality of pixel units. The leads of the driver chip need to be connected to scanning lines or data lines through fan-shaped traces. Generally speaking, among the fan-shaped traces, the length of the traces in the center is the shortest, and the length of the traces on two lateral sides is the largest. The difference in length brings the difference in impedance between the traces. And the greater the difference in length of the traces, the greater the difference in impedance. Therefore, in order to reduce the difference of the length of the traces, it is necessary to change the shape/layout of each trace so that the lengths of the traces tend to be the same for minimizing impedance difference of each trace. However, by changing the layout of the traces, the area occupied by the traces also increases, which is a disadvantages to the layout of the traces with limited space, thus making it difficult to minimize the impedance difference of each trace or even making it disappears.

Therefore, the present application provides a fanout trace layout.

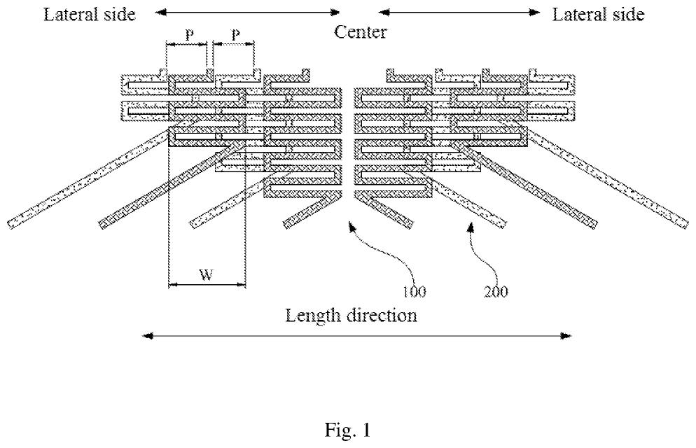

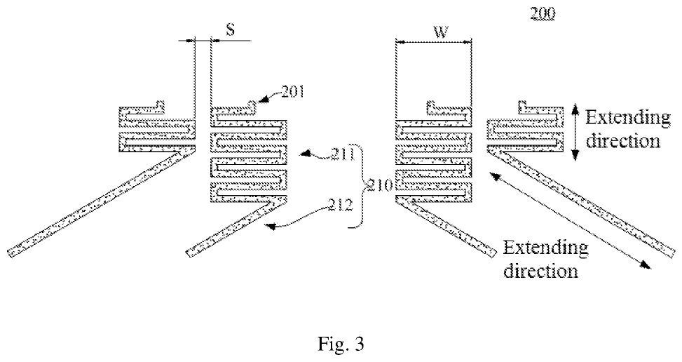

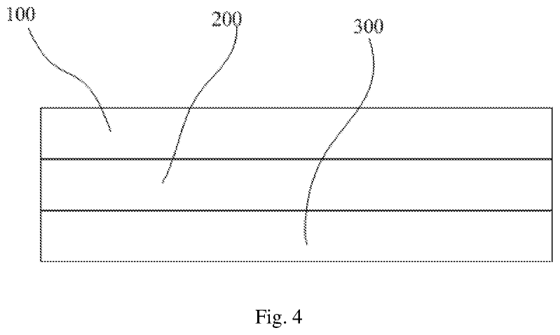

In some embodiments of the present application, referring to FIGS. 1 to 4, the fanout trace layout includes:

a first fanout layer 100 and a second fanout layer 200; and

an insulating layer 300 defined between the first fanout layer 100 and the second fanout layer 200. The first fanout layer 100, the insulating layer 200 and the second fanout layer 300 are defined from top to bottom.

The first fanout layer 100 includes a plurality of first traces 110 arranged at intervals. The second fanout layer 200 includes a plurality of second traces 210 arranged at intervals.

The first traces 110 and the second traces 210 are alternately defined, and the adjacent first traces 110 and the second traces 210 are partially overlapped.

In some embodiments, the first fanout layer 100 includes a plurality of first traces 110. And the second fanout layer 200 includes a plurality of second traces 210. The first traces 110 and the second traces 210 are insulated by the insulating layer 300 to ensure that there is no short circuit between the first traces 110 and the second traces 210, thereby avoiding interference in signal transmission.

The insulating layer 300 is made of an insulating material, and the insulating material can be selected according to actual requirements. The insulating layer 300, the first fanout layer 100 and the second fanout layer 200 can be combined into an integration to further ensure the structural stability of the first traces 110 and the second traces 210, preventing the first traces 110 and the second traces 210 from breaking. The combination of the first fanout layer 100, the insulating layer 300 and the second fanout layer 200 may be implemented that the second fanout layer 200 is formed by first preparing the second traces 210, then the insulating layer 300 is formed on the second fanout layer 200, and then the first traces 110 is prepared on the insulating layer 300 to form the first fanout layer 100. Thus the first fanout layer 100, the insulating layer 300 and the second fanout layer 200 is combined into an integration.

Specifically, the fanout trace layout can be molded on the substrate. First, the second traces 210 are formed on the substrate, then the insulating layer 300 is formed on the second traces 210, and finally the first traces 110 are formed on the insulating layer 300. In this way, the first traces 110, the insulating layer 300, the second traces 210 and the substrate are integrated, and the fanout trace layout is attached to the substrate.

A plurality of the first traces 110 are arranged at intervals to ensure the insulation between adjacent first traces 110, and the distance between adjacent first traces 110 can be set according to actual requirements without any other limitation. Similar to the layout of the first traces 110, the second traces 210 are spaced apart to ensure insulation between the adjacent second traces 210, and the distance between the adjacent second traces 210 can be set according to actual requirement without any other limitation.

The first traces 110 and the second traces 210 are alternately defined, and the adjacent first traces 110 and the second traces 210 are partially overlapped. In this way, with the two-layer layout of the first fanout layer 100 and the second fanout layer 200, the adjacent first and second traces 110 and 210 are partially overlapped, so that the space occupied by the fanout trace layout in the length direction (that is, the direction in which the first and second traces 110 and 210 are defined from the center to two lateral sides) can be reduced.

That is, in the case where the space in the length direction occupied by the fanout trace layout remains unchanged, the present application divides the fanout traces into the first traces 110 and the second traces 210, and placing the first traces 110 and the second traces 210 in a two-layer layout. Therefore, in the length direction of the fanout trace layout, different first and second traces 110 and 210 can have more space for the layout design of the traces, so that the impedance differences of the different first and second traces 110 and 210 can be adjusted. Even if the space occupied by each of the first and second traces 110 and 210 is increased, the space occupied by the fanout trace layout can be reduced by the two-layer layout and the overlapped layout.

In some embodiments, the fanout trace layout includes the first traces 110 and the second traces 210, and the first traces 110 and the second traces 210 are alternately defined, and the adjacent first traces 110 and the second traces 210 are partially overlapped, and the first traces 110 and the second traces 210 are insulated from each other. In this way, through the structural layout of at least two layers, that is, the first fanout layer 100 and the second fanout layer 200, when the space is compressed, the design space of the first traces 110 and the second traces 210 is greatly increased, so that the length of the different first traces 110 and the second traces 210 can be adjusted from the center to the lateral side, thereby minimizing the impedance difference between the first traces 110 and the second traces 210 and ensuring the stability of the signal transmittance.

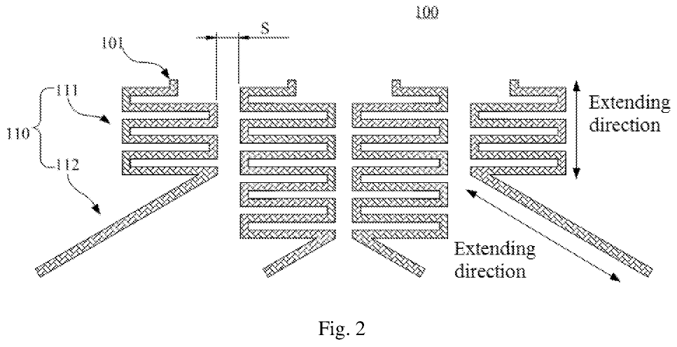

In some embodiments of the present application, referring to FIGS. 1 and 2, in which the first traces 110 includes a winding portion 111 and a straight portion 112, a plurality of the first traces 110 are defined in a direction from the center to two lateral sides, and the extending length of the winding portion 111 of the first traces 110 gradually decreases in the direction from the center to two lateral sides, and the extending length of the straight portion 112 of the first traces 110 gradually increases in the direction from the center to two lateral sides.

In some embodiments, the first traces 110 includes a winding portion 111 and a straight portion 112, the winding portion 111 of the first traces is defined to be electrically connected with the leads of the driving circuit, and the straight portion 112 is defined to be electrically connected with the data lines or signal lines in the active area. The winding portion 111 of the first traces can be wound in different shapes, such as in a zagged shape or in a [symbol] shape. The straight portion 112 of the first traces is a straight line accordingly. In some exemplary embodiments In some embodiments, the shapes of the winding portions 111 of each of the first traces are the same, thus improving the preparation efficiency of the first traces 110.

A plurality of the first traces 110 are defined from the center to two lateral sides, in the direction from the center to two lateral sides. The extending length of the winding portion 111 of the first traces gradually decreases, that is, the length of this portion of the first traces gradually decreases accordingly. The extending length of the straight portion 112 of the first traces gradually increases, that is, the length of this portion of the first traces gradually increases accordingly. In a limited space, the extent of extension of the winding portion 111 of the first traces gradually decreases, and the extending length of the straight portion 112 of the corresponding first traces increases synchronously. In this way, the traces length of the winding portion 111 of the first traces and the traces length of the straight portion 112 of the first traces are adjusted to ensure that the trace length of each of the first traces 110 tends to be the same in whole, thereby reducing impedance difference between each of the first traces 110.

In some embodiments of the present application, referring to FIGS. 1 to 3, the second traces 210 includes a winding portion 211 and a straight portion 212. A plurality of the second traces 210 are defined in a direction from the center to two lateral sides, and the extending length of the winding portion 211 of the second traces gradually decreases in the direction from the center to two lateral sides, and the extending length of the straight portion 212 of the second traces gradually increases in the direction from the center to two lateral sides.

In some embodiments, just like the first traces 110, the second traces 210 include a winding portion 211 and a straight portion 212. The winding portion 211 of the second traces is defined to be electrically connected to the leads of the driving circuit, and the straight portion 212 is defined to be electrically connected to the data lines or signal lines in the active area. The winding portion 211 of the second traces can be wound in different shapes, such as in a zagged shape or in a [symbol] shape. The straight portion 212 of the second traces is a straight line accordingly. In some embodiments, the shapes of the winding portions 211 of the second traces are the same, thus improving the preparation efficiency of the second traces 210.

A plurality of the second traces 210 are defined from the center to two lateral sides. In the direction from the center to two lateral sides, the extending length of the winding portion 211 of the second traces gradually decreases, that is, the length of this portion of the second traces gradually decreases accordingly, The extending length of the straight portion 212 of the second traces gradually increases, that is, the length of this portion of the second traces gradually decreases accordingly. In a limited space, the extent of extension of the winding portion 211 of the second traces gradually decreases, and the extending length of the straight portion 212 of the corresponding second traces increases synchronously. In this way, the adjustment of the traces length of the winding portion 211 of the second traces and the adjustment of the traces length of the straight portion 212 of the second traces ensure that the traces length of each of the second traces 210 tends to be the same, thereby reducing the impedance difference of each of the second traces 210.

In some embodiments of the present application, referring to FIGS. 1 to 3, the extending length of the winding portion 111 of the first traces is greater than the extending length of the winding portion 211 of the second traces that are adjacent to the first trace. The extending length of the straight portion 112 of the first traces is smaller than the extending length of the straight portion 212 of the second traces that are adjacent to the first trace.

Alternatively, the extending length of the winding portion 111 of the first traces is smaller than the extending length of the winding portion 211 of the second traces that are adjacent to the first trace. The extending length of the straight portion 112 of the first traces is greater than the extending length of the straight portion 212 of the second traces that are adjacent to the first trace.

In some embodiments, by setting up as above, that is, in the direction from the center to two lateral sides, the traces length of the winding portion 111 of the first traces and the traces length of the winding portion 211 of the second traces are sequentially decreased. The traces length of the straight portion 112 of the first traces and the traces length of the straight portion 212 of the second traces are sequentially increased. Which means, regarding the winding portion 111 of the first traces and the winding portion 111 of the second traces, the closer to the center, the greater the extending length of the winding portion (i.e., the longer the corresponding winding length of the winding portion). For the straight portion 112 of the first traces and the straight portion 212 of the second traces, the closer to the center, the smaller the extending length of the corresponding straight portion (i.e., the smaller the corresponding trace length of the straight portion). In this way, the impedance difference between each of the first traces 110 and each of the second traces 210 is ensured to minimize.

In some embodiments of the present application, referring to FIG. 1, the extending direction of the winding portion 111 of the first traces is perpendicular to the length direction of the first fanout layer 100. The extending direction of the straight portion 112 of the first traces is inclined to the length direction of the first fanout layer 100.

The extending direction of the winding portion 211 of the second traces is perpendicular to the length direction of the second fanout layer 200, and the extending direction of the straight portion 212 of the second traces is inclined to the length direction of the second fanout layer 200.

In some embodiments, the length direction of the first fanout layer 100 is the direction from one side to the other side of the first traces 110. In this way, the extending direction of the winding portion 111 of the first traces is perpendicular to the length direction of the first fanout layer 100, so that to extend the traces length with occupying the minimum space. The extending direction of the straight portion 112 of the first traces is inclined to the length direction of the first fanout layer 100, facilitating connection between the first traces and data lines or signal lines.

The layout of the second traces 210 is similar to that of the first traces 110 and will not be repeated herein.

In some embodiments of the present application, referring to FIGS. 1 to 3, the width of the winding portion 111 of the first traces is the same as the width of the winding portion 211 of the second traces.

In some embodiments, when the width of the winding portion 111 of the first traces is the same as the width of the winding portion 211 of the second traces, which is, when the extending length of the winding portion 111 of the first traces and the extending length of the winding portion 211 of the second traces change, the impedance changes accordingly. Therefore, when fixing the widths of the first winding portion 111 and the second winding portion 211, the impedance can be adjusted by adjusting the extending length of the corresponding winding portions of the first traces and the second traces without simultaneously adjusting the width and extending length of the winding portion 111 and the winding portion 211 to improve the production efficiency.

In some embodiments of the present application, referring to FIGS. 1 to 3, the winding portion 111 of the first traces is formed with leads 101, and the winding portion 211 of the second traces is formed with leads 201. The distance between the adjacent leads 101 of the first traces and the leads 201 of the second traces is P. The distance between the winding portion 111 of the adjacent first traces and the distance between the winding portion 211 of the adjacent second traces are S, respectively. The width of the winding portion of the first trace is W, and the width of the winding portion of the second trace is W, and p<w≤2p−s.

If the adjacent first traces 110 and the second traces 210 do not overlap, the width W satisfies W=P−S. In some embodiments, the width of the winding portion 111 of the first traces and the width w of the winding portion 211 of the second traces satisfy P<W<=2P−S. Through partial overlapping of the adjacent first traces 110 and the second traces 210, the width W is greatly increased compared with the non-overlapped layout, so that the traces paths of the winding portion 111 of the first traces and the winding portion 211 of the second traces can be increased to adjust the impedance in a better way. Moreover, the width W satisfies P<W≤2P−S to reduce the capacitance load. The signal delay is thus reduced by reducing the capacitance load.

In some embodiments of the present application, the insulating layer 300 is a nitro-silicide layer.

In some embodiments, the silicon nitride compound layer (SiNx) can provide good insulation performance and ensure mutual insulation between the first fanout layer and the second fanout layer.

The present application also discloses a display panel.

In one embodiment of the present application, the display panel includes the fanout trace layout as described above.

In one embodiment, the display panel includes a driving chip and an active area containing pixels, and the fanout trace layout is electrically connected to the driving chip and the active area, respectively. The specific layout of the fanout trace layout refers to the above embodiment. Since the fanout trace layout of the display panel in some embodiments adopts all the technical solutions of all the previous-mentioned embodiments, it may have at least all the effects brought about by the technical solutions of the previous-mentioned embodiments and will not be described in detail herein.

The application also discloses a display device.

In some embodiments of the present application, the display device includes a display panel as described above.

In one embodiment, the display device includes a display panel and a backlight module as described above. The specific layout of the display panel refers to the above embodiments. Since the display panel of the display device in some embodiments adopts all the technical solutions of all the previous-mentioned embodiments, it may have at least all the effects brought about by the technical solutions of the previous-mentioned embodiments and will not be described herein.

The above is only the preferred embodiment of the present application and is not therefore limiting the scope of the present application. Any equivalent structural change made under the concept of the present application using the contents of the present application specification and drawings, or directly/indirectly applied in other related technical fields, shall be included in the protection scope of the present application.

What is claimed is:

1. A fanout trace layout, wherein, the fanout trace layout comprises:
a first fanout layer and a second fanout layer; and
an insulating layer, defined between the first fanout layer and the second fanout layer; the first fanout layer, the insulating layer, and the second fanout layer are arranged from the top to the bottom of the fanout trace layout;
the first fanout layer comprises a plurality of first traces arranged at intervals; the second fanout layer comprises a plurality of second traces arranged at intervals;
the first trace and the second trace are alternately defined, the adjacent first trace and the second trace partially overlap.

2. The fanout trace layout of claim 1, wherein, the first traces comprises a winding portion and a straight portion, the first traces are defined in a direction from the center to two lateral sides, and an extending length of the winding portion of the first trace gradually decreases in the direction from the center to two lateral sides, while an extending length of the straight portion of the first trace gradually increases in the direction from the center to two lateral sides.

3. The fanout trace layout of claim 2, wherein, the second traces comprises a winding portion and a straight portion, the second traces are defined in the direction from the center to two lateral sides, and an extending length of the winding portion of the second trace gradually decreases in the direction from the center to two lateral sides, while an extending length of the straight portion of the second trace gradually increases in the direction from the center to two lateral sides.

4. The fanout trace layout of claim 3, wherein, the extending length of the winding portion of the first trace is larger than the extending length of the winding portion of the second trace that are adjacent to the first trace, and the extending length of the straight portion of the first trace is smaller than the extending length of the straight portion of the second trace that are adjacent to the first trace.

5. The fanout layout of claim 3, wherein, the extending length of the winding portion of the first trace is smaller than the extending length of the winding portion of the second trace that are adjacent to the first trace, and the extending length of the straight portion of the first trace is larger than the extending length of the straight portion of the second trace that are adjacent to the first trace.

6. The fanout trace layout of claim 3, wherein, an extending direction of the winding portion of the first trace is perpendicular to a length direction of the first fanout layer, and an extending direction of the straight portion of the first trace is inclined to the length direction of the first fanout layer;
an extending direction of the winding portion of the second trace is perpendicular to a length direction of the second fanout layer, and an extending direction of the straight portion of the second trace is inclined to the length direction of the second fanout layer.

7. The fanout wire layout of claim 3, wherein, a width of the winding portion of the first trace is the same as a width of the winding portion of the second trace.

8. The fanout wire layout of claim 7, wherein, a first lead is formed at the winding portion of the first trace, a second lead is formed at the winding portion of the second trace, a distance between the first lead of first traces and the second lead of the second traces that are adjacent to the first trace is P, a distance between two adjacent winding portions of the first traces is S, and a distance between two adjacent winding portions of the second traces is S, a width of the winding portion of the first trace is W, and a width of the winding portion of the second trace is W, and p<w≤2p−s.

9. The fanout trace layout of claim 1, wherein, the insulating layer is a nitro-silicide layer.

10. A display panel, wherein, the display panel comprises a fanout trace layout, the fanout trace layout comprises:
a first fanout layer and a second fanout layer; and
an insulating layer, defined between the first fanout layer and the second fanout layer, the first fanout layer, the insulating layer and the second fanout layer are arranged from top to bottom;
the first fanout layer comprises a plurality of first traces arranged at intervals; the second fanout layer comprises a plurality of second traces arranged at intervals;
the first trace and the second trace are alternately defined, and the adjacent first traces and the second traces partially overlap.

11. The display panel of claim 10, wherein, the first traces comprises a winding portion and a straight portion, the first traces are defined in a direction from the center to two lateral sides, and an extending length of the winding portion of the first trace gradually decreases in the direction from the center to two lateral sides, while an extending length of the straight portion of the first trace gradually increases in the direction from the center to two lateral sides.

12. The display panel of claim 11, wherein, the second traces comprises a winding portion and a straight portion, the second traces are defined in a direction from the center to two lateral sides, and an extending length of the winding portion of the second trace gradually decreases in the direction from the center to two lateral sides, while an extending length of the straight portion of the second trace gradually increases in the direction from the center to two lateral sides.

13. The display panel of claim 12, wherein, the extending length of the winding portion of the first trace is larger than the extending length of the winding portion of the second trace that are adjacent to the first trace, and the extending length of the straight portion of the first trace is smaller than the extending length of the straight portion of the second trace that are adjacent to the first trace.

14. The display panel of claim 12, wherein, the extending length of the winding portion of the first trace is smaller than the extending length of the winding portion of the second trace that are adjacent to the first trace, and the extending length of the straight portion of the first trace is larger than the extending length of the straight portion of the second trace that are adjacent to the first trace.

15. The display panel of claim 12, wherein, an extending direction of the winding portion of the first trace is perpendicular to a length direction of the first fanout layer, and an extending direction of the straight portion of the first trace is inclined to the length direction of the first fanout layer;
an extending direction of the winding portion of the second trace is perpendicular to a length direction of the second fanout layer, and an extending direction of the straight portion of the second trace is inclined to the length direction of the second fanout layer.

16. The display panel of claim 12, wherein, a width of the winding portion of the first trace is the same as a width of the winding portion of the second trace.

17. The display panel of claim 16, wherein, a first lead is formed at the winding portion of the first trace, a second lead is formed at the winding portion of the second trace, a distance between the first lead of first traces and the second lead of the second traces that are adjacent to the first trace is P, a distance between two adjacent winding portions of the first traces is S, and a distance between two adjacent winding portions of the second traces is S, a width of the winding portion of the first trace is W, and a width of the winding portion of the second trace is W, and p<w≤2p−s.

18. The display panel of claim 10, wherein, the insulating layer is a nitro-silicide layer.

19. The display panel according to claim 10, wherein, the display panel further comprises a substrate, and the second traces, the insulating layer and the first traces are defined on the substrate.

20. A display device, wherein, the display device comprises a display panel, the display panel comprising a fanout trace layout, the fanout trace layout comprises:
a first fanout layer and a second fanout layer; and
an insulating layer, defined between the first fanout layer and the second fanout layer, the first fanout layer, the insulating layer and the second fanout layer are arranged from top to bottom;
the first fanout layer comprises a plurality of first traces arranged at intervals; the second fanout layer comprises a plurality of second traces arranged at intervals;
the first trace and the second trace are alternately defined, and the first traces and the second traces partially overlap when the first traces and the second traces are adjacently defined.
